(19) United States
(12) Patent Application Publication
(10) Pub. No.: US 2025/0112166 A1
(43) Pub. Date: Apr. 3, 2025

(54) FLIP CHIP PACKAGE AND FABRICATION METHOD THEREOF

(71) Applicant: MEDIATEK INC., Hsinchu City (TW)

(72) Inventors: Pei-Haw Tsao, Hsinchu City (TW); Te-Chi Wong, Hsinchu City (TW)

(73) Assignee: MEDIATEK INC., Hsinchu City (TW)

(21) Appl. No.: 18/892,518

(22) Filed: Sep. 22, 2024

Related U.S. Application Data
(60) Provisional application No. 63/585,978, filed on Sep. 28, 2023.

(51) Int. Cl. H01L 23/538; H01L 23/00; H01L 23/14; H01L 23/31; H01L 25/00; H01L 25/18; H10B 80/00

(52) U.S. Cl. CPC H01L 23/5386; H01L 25/18; H01L 25/50; H01L 23/145; H01L 23/3107; H01L 24/16; H01L 24/32; H01L 24/73; H01L 2224/16227; H01L 2224/32225; H01L 2224/73204; H10B 80/00

(57) ABSTRACT

A flip-chip package includes a substrate having a bond pad in a die-mounting area of the substrate. A DRAM die is mounted on the die-mounting area of the substrate in a flip chip fashion. The DRAM die includes an input/output (I/O) pad on its active surface and the I/O pad is electrically coupled to the t bond pad through a connecting element. The bond pad has a diameter that is smaller than a diameter of the I/O pad. A SoC die is mounted on the substrate in a flip chip fashion. The DRAM die and the SoC die are mounted on the substrate in a side-by-side manner.

### CROSS REFERENCE TO RELATED APPLICATIONS

This application claims the benefit of U.S. Provisional Application No. 63/585,978, filed on Sep. 28, 2023. The content of the application is incorporated herein by reference.

### BACKGROUND

The present disclosure relates generally to the field of semiconductor packaging. More particularly, the present disclosure relates to an improved flip-chip package.

Innovations in semiconductor manufacturing and semiconductor packaging technologies have enabled the development of smaller scale, higher density integrated circuit (IC) chips (or die) as well as the development of highly integrated chip modules with wiring and area array input/output (I/O) contact densities that enable dense packaging of IC chips (or die).

There is a continuing demand for IC chips with increasing integrated functionality and smaller footprints, leading to increases in I/O count and I/O density of IC chips. In addition, high-performance, high-density integrated packaging solutions typically require small micro-bumps for flip-chip connectivity.

2.5-D packaging techniques have been used to increase I/O density and provide high-density routing for low-power chip-to-chip transmission. In general, 2.5-D integration involves flip-chip bonding of multiple IC dies onto a passive interposer substrate where the passive interposer substrate is bonded to a packaging substrate. Compared to the packaging substrate, the interposer features finer pitch wiring, higher pad densities, and reduced die-to-die interconnect spacing.

### SUMMARY

It is one object of the invention to provide an improved flip-chip package and a fabrication method thereof, in order to solve the deficiencies or shortcomings of the prior art.

One aspect of the invention provides a flip-chip package including a substrate having a top surface and a bottom surface opposite to the top surface. The substrate includes at least one first bond pad in a first die-mounting area of the substrate and at least one second bond pad in a second die-mounting area of the substrate. The at least one first bond pad has a diameter X1 and the at least one second bond pad has a diameter Y1.

A first electronic component is mounted on the first die-mounting area of the substrate in a flip chip fashion. The first electronic component includes at least one first input/output (I/O) pad on its active surface and the at least one first I/O pad is electrically coupled to the at least one first bond pad through a first connecting element. The at least one first I/O pad has a diameter X, wherein X1 is smaller than X.

A second electronic component is mounted on the second die-mounting area of the substrate in a flip chip fashion. The second electronic component includes at least one second input/output (I/O) pad on its active surface and the at least one second I/O pad is electrically coupled to the at least one second bond pad through a second connecting element. The at least one second I/O pad has a diameter Y, wherein Y1 substantially equals to Y.

According to some embodiments, the first electronic component comprises a DRAM die or a DRAM kgd, and wherein the second electronic component comprises a SoC die.

According to some embodiments, the substrate comprises an organic substrate or a plastic substrate.

According to some embodiments, the substrate comprises a build-up structure including at least one dielectric layer, at least one wiring layer, and at least one via electrically connecting the first bond pad to the at least one wiring layer.

According to some embodiments, the substrate has a substrate size that is greater than or equal to 12 mm×12 mm.

According to some embodiments, the substrate comprises a solder mask layer around the at least one first bond pad and the at least one second bond pad.

According to some embodiments, the substrate comprises a pad diameter ratio X1/X of about 0.5 and a pad diameter ratio Y1/Y of about 1.0.

According to some embodiments, a gap between the first electronic component and the top surface of the substrate is filled with a first underfill and a gap between the second electronic component and the top surface of the substrate is filled with a second underfill.

According to some embodiments, the first electronic component and the second electronic component are encapsulated together by using a molding compound.

According to some embodiments, a plurality of third connecting elements is disposed on the bottom surface of the substrate.

Another aspect of the invention provides a method for forming a flip-chip package. A substrate having a top surface and a bottom surface is provided. The substrate includes at least one first bond pad in a first die-mounting area of the substrate and at least one second bond pad in a second die-mounting area of the substrate. The at least one first bond pad has a diameter X1 and the at least one second bond pad has a diameter Y1.

A first electronic component is mounted on the first die-mounting area of the substrate in a flip chip fashion. The first electronic component includes at least one first input/output (I/O) pad on its active surface and the at least one first I/O pad is electrically coupled to the at least one first bond pad through a first connecting element. The at least one first I/O pad has a diameter X, and wherein X1 is smaller than X.

A second electronic component is mounted on the second die-mounting area of the substrate in a flip chip fashion. The second electronic component includes at least one second input/output (I/O) pad on its active surface and the at least one second I/O pad is electrically coupled to the at least one second bond pad through a second connecting element. The at least one second I/O pad has a diameter Y, and wherein Y1 substantially equals to Y.

According to some embodiments, the first electronic component comprises a DRAM die or a DRAM kgd, and wherein the second electronic component comprises a SoC die.

According to some embodiments, the substrate comprises an organic substrate or a plastic substrate.

According to some embodiments, the substrate comprises a build-up structure including at least one dielectric layer, at least one wiring layer, and at least one via electrically connecting the first bond pad to the at least one wiring layer.

According to some embodiments, the substrate has a substrate size that is greater than or equal to 12 mm×12 mm.

According to some embodiments, the substrate comprises a solder mask layer around the at least one first bond pad and the at least one second bond pad.

According to some embodiments, the substrate comprises a pad diameter ratio X1/X of about 0.5 and a pad diameter ratio Y1/Y of about 1.0.

According to some embodiments, the method further includes the steps of filling a gap between the first electronic component and the top surface of the substrate with a first underfill; and filling a gap between the second electronic component and the top surface of the substrate with a second underfill.

According to some embodiments, the method further includes the step of encapsulating the first electronic component and the second electronic component together by using a molding compound.

According to some embodiments, the method further includes the step of forming a plurality of third connecting elements on the bottom surface of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic plan view of a semiconductor package in accordance with an embodiment of the invention;

FIG. 2 is a schematic, cross-sectional view taken along line I-I′ in FIG. 1; and

FIG. 3 to FIG. 6 are schematic diagrams showing an exemplary method for forming a semiconductor package according to an embodiment of the invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, structural, and procedural changes may be made without departing from the spirit and scope of the present disclosure. The following detailed description is, therefore, not to be taken in a limiting sense, and the scope of embodiments of the present invention is defined only by the appended claims.

It will be understood that, although the terms first, second, third, primary, secondary, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first or primary element, component, region, layer or section discussed below could be termed a second or secondary element, component, region, layer or section without departing from the teachings of the present inventive concept.

Spatially relative terms, such as “beneath”, “below”, “lower”, “under”, “above,” “upper,” “over” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” or “over” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present. The term “system on chip” or “SoC” refers to an integrated circuit that integrates various components of a computer or other electronic system into a single chip. The term “kgd” or “KGD” refers to a known good die.

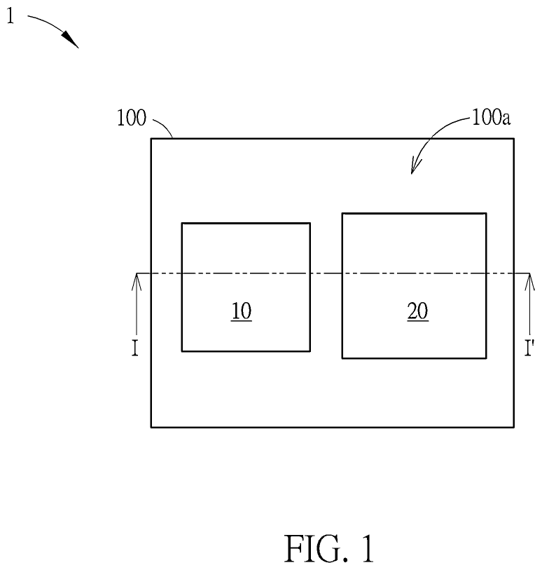

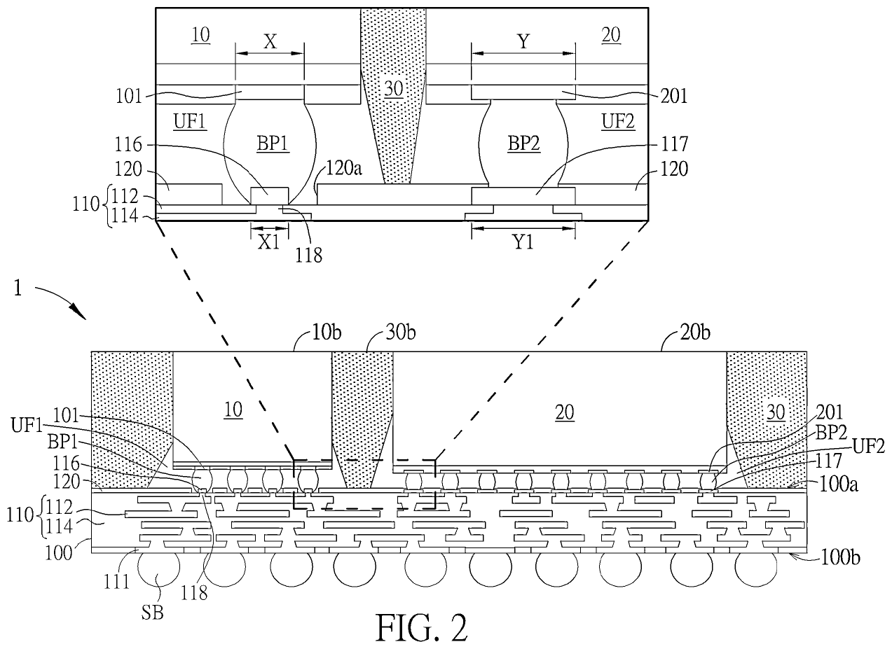

Please refer to FIG. 1 and FIG. 2. FIG. 1 is a schematic plan view of a semiconductor package in accordance with an embodiment of the invention. FIG. 2 is a schematic, cross-sectional view taken along line I-I′ in FIG. 1. The semiconductor package 1 comprises a substrate 100, for example, an interposer substrate or a packaging substrate, but is not limited thereto. According to some embodiments of the invention, the substrate 100 may be an organic substrate or a plastic substrate. According to some embodiments of the invention, the substrate 100 may be a cored substrate or a coreless substrate.

According to an embodiment of the invention, as can be seen in the enlarged portion in FIG. 2, the substrate 100 may comprise a build-up structure 110 including at least one dielectric layer 112 and at least one wiring layer 114. According to an embodiment of the invention, the substrate 100 may further comprise at least one bond pad 116 on the top surface 100a and a via 120 electrically connecting the bond pad 116 to the underlying wiring layer 114. According to an embodiment of the invention, the substrate 100 may further comprise a solder mask layer 120 around the bond pad 116. According to an embodiment of the invention, the bond pad 116 may be a Non-Solder Mask Defined (NSMD) pad. According to some embodiments of the invention, the bond pad 116 may be a Solder Mask Defined (SMD) pad. According to an embodiment of the invention, the bond pad 116 has a diameter X1, for example, X1 may range between 100-220 micrometers.

According to an embodiment of the invention, the substrate 100 may have a substrate size that is greater than or equal to 12 mm×12 mm. According to an embodiment of the invention, the substrate 100 includes a top surface 100a and a bottom surface 100b that is opposite to the top surface 100a.

According to an embodiment of the invention, the semiconductor package 1 comprises a first electronic component 10 mounted on the top surface 100a of the substrate 100. According to an embodiment of the invention, the first electronic component 10 may be a dynamic random access memory (DRAM) die or a DRAM kgd, for example, a double data rate 3 (DDR3) DRAM die or a double data rate 4 (DDR4) DRAM die. According to an embodiment of the invention, the first electronic component 10 is mounted onto the top surface 100a of the substrate 100 in a flip-chip fashion.

According to an embodiment of the invention, the first electronic component 10 comprises at least one input/output (I/O) pad 101 on its active surface and the I/O pad 101 is electrically coupled to the corresponding bond pad 116 through a connecting element BP1. The bond pad 116 is disposed directly under the first electronic component 10. According to an embodiment of the invention, for example, the connecting element BP1 may comprise a solder bump or a metal bump such as a copper pillar with solder cap, but is not limited thereto. According to an embodiment of the invention, the I/O pad 101 may have a diameter X, for example, X may range between 180-350 micrometers. According to an embodiment of the invention, the diameter X1 of the bond pad 116 is smaller than the diameter X of the I/O pad 101 of the first electronic component 10. According to an embodiment of the invention, for example, the diameter ratio X1/X is about 0.5. By providing such configuration, the routing space to the center of the first electronic component 10 may be released.

According to an embodiment of the invention, a gap between the first electronic component 10 and the top surface 100a of the substrate 100 may be filled with an underfill UF1. According to an embodiment of the invention, for example, the underfill UF1 may comprise epoxy resin, but is not limited thereto. According to an embodiment of the invention, underfill UF1 surrounds the connecting elements BP1 and may fill into the solder mask openings 120a.

According to an embodiment of the invention, the semiconductor package 1 comprises a second electronic component 20 mounted on the top surface 100a of the substrate 100. The second electronic component 20 is disposed in close proximity to the first electronic component 10. According to an embodiment of the invention, for example, the first electronic component 10 may be a System on Chip (SoC) die including, but not limited to, a memory controller for controlling the DRAM die, an Intellectual Property (IP), a Central Processing Unit (CPU) for controlling the memory controller and the IP, a system bus for interconnecting the memory controller, the IP, or the CPU, etc. The IP may access the memory die through the memory controller.

According to an embodiment of the invention, the first electronic component 10 and the second electronic component 20 are mounted on the first surface 100a of the substrate 100 in a side-by-side manner. According to an embodiment of the invention, the second electronic component 20 comprises at least one input/output (I/O) pad 201 on its active surface and the I/O pad 201 is electrically coupled to the corresponding bond pad 117 through a connecting element BP2. According to an embodiment of the invention, for example, the connecting element BP2 may comprise a solder bump or a metal bump such as a copper pillar with solder cap, but is not limited thereto.

According to an embodiment of the invention, the I/O pad 201 may have a diameter Y, for example, Y may range between 180-350 micrometers. According to an embodiment of the invention, the bond pad 117 has a diameter Y1, for example, Y1 may range between 100-220 micrometers. According to an embodiment of the invention, the diameter Y1 of the bond pad 117 substantially equals to the diameter Y of the I/O pad 201 of the second electronic component 20. According to an embodiment of the invention, for example, the diameter ratio Y1/Y is about 1.0. The substrate 100 comprises an array of bond pads 116 directly under the first electronic component 10 and an array of bond pads 117 directly under the second electronic component 20, and the bond pads 116 and 117 have different pad sizes.

According to an embodiment of the invention, likewise, a gap between the second electronic component 20 and the top surface 100a of the substrate 100 may be filled with an underfill UF2. According to an embodiment of the invention, for example, the underfill UF2 may comprise epoxy resin, but is not limited thereto.

According to an embodiment of the invention, the first electronic component 10 and the second electronic component 20 are encapsulated together by using a molding compound 30. The rear surface 10b of the first electronic component 10 and the rear surface 20b of the second electronic component 20 are exposed from the molding compound 30. According to an embodiment of the invention, the rear surface 10b of the first electronic component 10, the rear surface 20b of the second electronic component 20, and the top surface 30a of the molding compound 30 are coplanar.

According to an embodiment of the invention, the semiconductor package 1 may further comprise bond pads 111 on the bottom surface 100b of the substrate 100 and connecting elements SB disposed on the ball pads 111, respectively, on the bottom surface 100b of the substrate 100. According to an embodiment of the invention, for example, the connecting elements SB may comprise C4 bumps, but is not limited thereto.

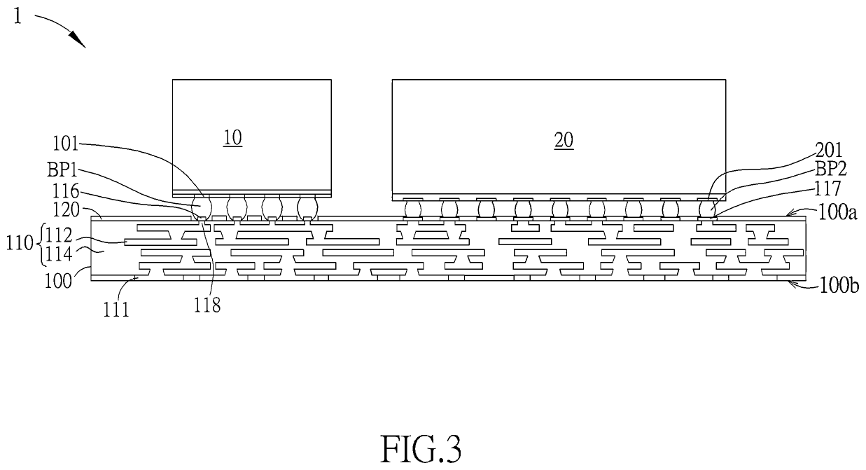

FIG. 3 to FIG. 6 are schematic diagrams showing an exemplary method for forming a semiconductor package according to an embodiment of the invention. As shown in FIG. 3, a substrate 100 is provided. According to some embodiments of the invention, the substrate 100 may be an organic substrate or a plastic substrate. According to some embodiments of the invention, the substrate 100 may be a cored substrate or a coreless substrate. The substrate 100 may comprise a build-up structure 110 including at least one dielectric layer 112 and at least one wiring layer 114. According to an embodiment of the invention, the substrate 100 may have a substrate size that is greater than or equal to 12 mm×12 mm.

According to an embodiment of the invention, the substrate 100 may further comprise at least one bond pad 116 on the top surface 100a and at least one via 120 electrically connecting the bond pad 116 to the underlying wiring layer 114. According to an embodiment of the invention, the substrate 100 may further comprise a solder mask layer 120 around the bond pad 116. According to an embodiment of the invention, for example, the bond pad 116 may be a NSMD pad. According to an embodiment of the invention, the bond pad 116 has a diameter X1, for example, X1 may range between 100-220 micrometers. According to an embodiment of the invention, the substrate 100 may further comprise at least one bond pad 117 on the top surface 100a of the substrate 100. According to an embodiment of the invention, the bond pad 117 has a diameter Y1, for example, Y1 may range between 180-350 micrometers. The bond pads 116 and 117 have different pad sizes.

Subsequently, a first electronic component 10 and a second electronic component 20 are mounted on the top surface 100a of the substrate 100 in a flip chip fashion. According to an embodiment of the invention, the first electronic component 10 may be a DRAM die or a DRAM kgd, for example, a DDR3 DRAM die or a DDR4 DRAM die. The second electronic component 20 may be a SoC die.

According to an embodiment of the invention, the first electronic component 10 comprises at least one I/O pad 101 on its active surface and the I/O pad 101 is electrically coupled to the corresponding bond pad 116 through a connecting element BP1. The bond pad 116 is disposed directly under the first electronic component 10. According to an embodiment of the invention, for example, the connecting element BP1 may comprise a solder bump or a metal bump such as a copper pillar with solder cap, but is not limited thereto. According to an embodiment of the invention, the I/O pad 101 may have a diameter X, for example, X may range between 180-350 micrometers. According to an embodiment of the invention, the diameter X1 of the bond pad 116 is smaller than the diameter X of the I/O pad 101 of the first electronic component 10. According to an embodiment of the invention, for example, the diameter ratio X1/X is about 0.5.

According to an embodiment of the invention, the second electronic component 20 comprises at least one input/output (I/O) pad 201 on its active surface and the I/O pad 201 is electrically coupled to the corresponding bond pad 117 through a connecting element BP2. According to an embodiment of the invention, for example, the connecting element BP2 may comprise a solder bump or a metal bump such as a copper pillar with solder cap, but is not limited thereto. According to an embodiment of the invention, the I/O pad 201 may have a diameter Y, for example, Y may range between 180-350 micrometers. According to an embodiment of the invention, the diameter Y1 of the bond pad 117 substantially equals to the diameter Y of the I/O pad 201 of the second electronic component 20. According to an embodiment of the invention, for example, the diameter ratio Y1/Y is about 1.0.

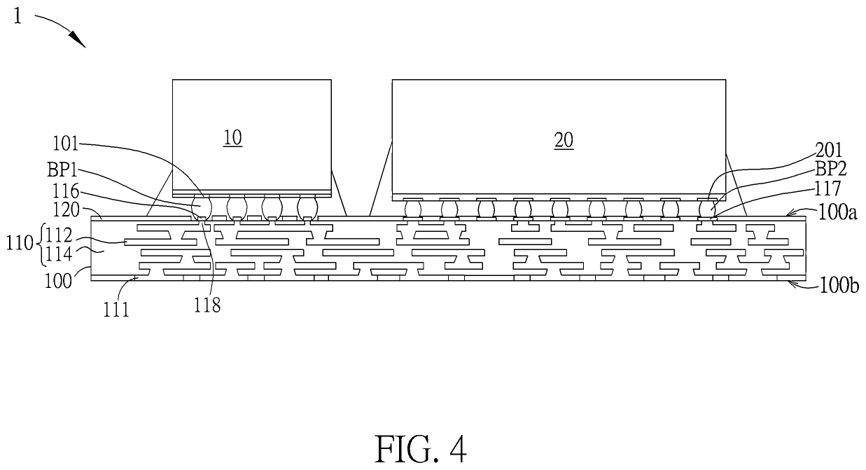

As shown in FIG. 4, a gap between the first electronic component 10 and the top surface 100a of the substrate 100 may be filled with an underfill UF1. According to an embodiment of the invention, for example, the underfill UF1 may comprise epoxy resin, but is not limited thereto. According to an embodiment of the invention, underfill UF1 surrounds the connecting elements BP1. A gap between the second electronic component 20 and the top surface 100a of the substrate 100 may be filled with an underfill UF2. According to an embodiment of the invention, for example, the underfill UF2 may comprise epoxy resin, but is not limited thereto. According to an embodiment of the invention, underfill UF2 surrounds the connecting elements BP2.

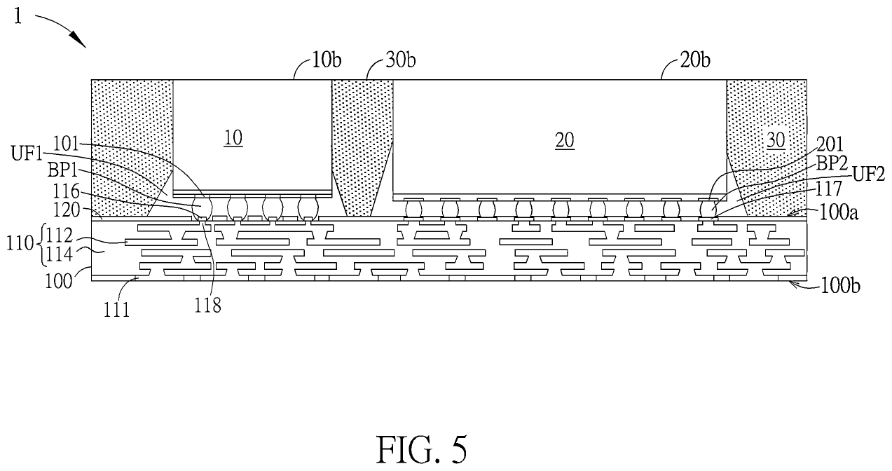

As shown in FIG. 5, the first electronic component 10 and the second electronic component 20 are encapsulated together by using a molding compound 30. Subsequently, the molding compound 30 may be subjected to a grinding process and/or a polishing process. The rear surface 10b of the first electronic component 10 and the rear surface 20b of the second electronic component 20 are exposed from the molding compound 30. According to an embodiment of the invention, the rear surface 10b of the first electronic component 10, the rear surface 20b of the second electronic component 20, and the top surface 30a of the molding compound 30 are coplanar.

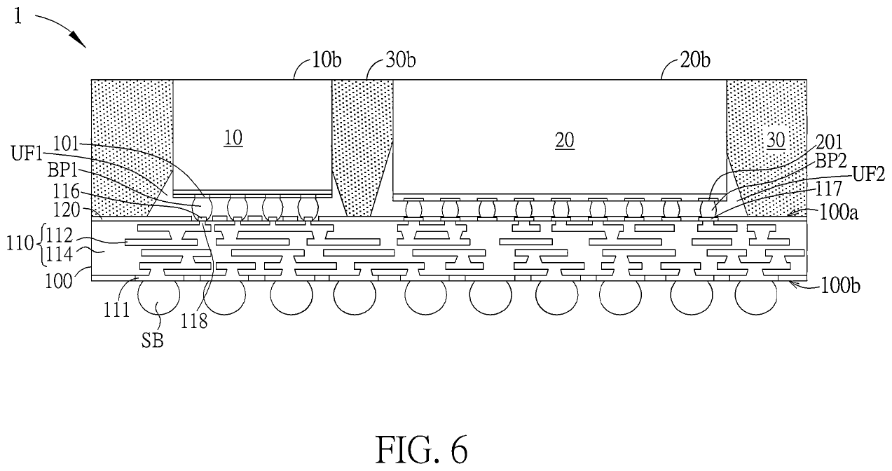

As shown in FIG. 6, connecting elements SB are then disposed on the ball pads 111, respectively, on the bottom surface 100b of the substrate 100. According to an embodiment of the invention, for example, the connecting elements SB may comprise C4 bumps, but is not limited thereto.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flip-chip package, comprising:
a substrate having a top surface and a bottom surface opposite to the top surface, wherein the substrate comprises at least one first bond pad in a first die-mounting area of the substrate and at least one second bond pad in a second die-mounting area of the substrate, wherein the at least one first bond pad has a diameter X1 and the at least one second bond pad has a diameter Y1;
a first electronic component mounted on the first die-mounting area of the substrate in a flip chip fashion, wherein the first electronic component comprises at least one first input/output (I/O) pad on its active surface and the at least one first I/O pad is electrically coupled to the at least one first bond pad through a first connecting element, wherein the at least one first I/O pad has a diameter X, and wherein X1 is smaller than X; and
a second electronic component mounted on the second die-mounting area of the substrate in a flip chip fashion, wherein the second electronic component comprises at least one second input/output (I/O) pad on its active surface and the at least one second I/O pad is electrically coupled to the at least one second bond pad through a second connecting element, wherein the at least one second I/O pad has a diameter Y, and wherein Y1 substantially equals to Y.

2. The flip-chip package according to claim 1, wherein the first electronic component comprises a DRAM die or a DRAM kgd, and wherein the second electronic component comprises a SoC die.

3. The flip-chip package according to claim 1, wherein the substrate comprises an organic substrate or a plastic substrate.

4. The flip-chip package according to claim 1, wherein the substrate comprises a build-up structure including at least one dielectric layer, at least one wiring layer, and at least one via electrically connecting the first bond pad to the at least one wiring layer.

5. The flip-chip package according to claim 1, wherein the substrate has a substrate size that is greater than or equal to 12 mm×12 mm.

6. The flip-chip package according to claim 1, wherein the substrate comprises a solder mask layer around the at least one first bond pad and the at least one second bond pad.

7. The flip-chip package according to claim 1, wherein the substrate comprises a pad diameter ratio X1/X of about 0.5 and a pad diameter ratio Y1/Y of about 1.0.

8. The flip-chip package according to claim 1, wherein a gap between the first electronic component and the top surface of the substrate is filled with a first underfill and a gap between the second electronic component and the top surface of the substrate is filled with a second underfill.

9. The flip-chip package according to claim 1, wherein the first electronic component and the second electronic component are encapsulated together by using a molding compound.

10. The flip-chip package according to claim 1, wherein a plurality of third connecting elements is disposed on the bottom surface of the substrate.

11. A method for forming a flip-chip package, comprising:
providing a substrate having a top surface and a bottom surface opposite to the top surface, wherein the substrate comprises at least one first bond pad in a first die-mounting area of the substrate and at least one second bond pad in a second die-mounting area of the substrate, wherein the at least one first bond pad has a diameter X1 and the at least one second bond pad has a diameter Y1;
mounting a first electronic component on the first die-mounting area of the substrate in a flip chip fashion, wherein the first electronic component comprises at least one first input/output (I/O) pad on its active surface and the at least one first I/O pad is electrically coupled to the at least one first bond pad through a first connecting element, wherein the at least one first I/O pad has a diameter X, and wherein X1 is smaller than X; and
mounting a second electronic component on the second die-mounting area of the substrate in a flip chip fashion, wherein the second electronic component comprises at least one second input/output (I/O) pad on its active surface and the at least one second I/O pad is electrically coupled to the at least one second bond pad through a second connecting element, wherein the at least one second I/O pad has a diameter Y, and wherein Y1 substantially equals to Y.

12. The method according to claim 11, wherein the first electronic component comprises a DRAM die or a DRAM kgd, and wherein the second electronic component comprises a SoC die.

13. The method according to claim 11, wherein the substrate comprises an organic substrate or a plastic substrate.

14. The method according to claim 11, wherein the substrate comprises a build-up structure including at least one dielectric layer, at least one wiring layer, and at least one via electrically connecting the first bond pad to the at least one wiring layer.

15. The method according to claim 11, wherein the substrate has a substrate size that is greater than or equal to 12 mm×12 mm.

16. The method according to claim 11, wherein the substrate comprises a solder mask layer around the at least one first bond pad and the at least one second bond pad.

17. The method according to claim 11, wherein the substrate comprises a pad diameter ratio X1/X of about 0.5 and a pad diameter ratio Y1/Y of about 1.0.

18. The method according to claim 11 further comprising:
filling a gap between the first electronic component and the top surface of the substrate with a first underfill; and
filling a gap between the second electronic component and the top surface of the substrate with a second underfill.

19. The method according to claim 11 further comprising:
encapsulating the first electronic component and the second electronic component together by using a molding compound.

20. The method according to claim 11 further comprising:
forming a plurality of third connecting elements on the bottom surface of the substrate.
